(19) United States
(12) Patent Application Publication
(10) Pub. No.: US 2005/0258427 A1
(43) Pub. Date: Nov. 24, 2005

(54) Vertical thin film transistor electronics

(76) Inventors: Isaac Wing Tak Chan, Waterloo (CA); Arokia Nathan, Waterloo (CA)

Correspondence Address: SMART AND BIGGAR, 438 UNIVERSITY AVENUE, SUITE 1500 BOX 111, TORONTO, ON, M5G2K8, CA

(21) Appl. No.: 11/133,411

(22) Filed: May 20, 2005

Related U.S. Application Data
(60) Provisional application No. 60/572,501, filed on May 20, 2004.

(51) Int. Cl. H01L 29/04

(52) U.S. Cl. 257/72

(57) ABSTRACT

Disclosed here is the design of a new vertical thin film transistor (VTFT) using hydrogenated amorphous silicon (a-Si:H) technology. This design allows the channel length to be scaled down to nanometer-scale (100 nm and beyond) as well as the smallest possible TFT size on glass, plastic, or other common types of substrates, based on the standard photo-etching and thin film deposition processes. The emphasis of using the standard processes for the new VTFTs has a strong implication that no additional process equipment and capital investments are required for technological advancements and gains in performance.

### CROSS-REFERENCE TO RELATED APPLICATIONS

The present application claims the benefit of prior provisional application Ser. No. 60/572,501, filed May 20, 2004, the contents of which are hereby incorporated herein by reference.

### BRIEF DESCRIPTION OF THE DRAWINGS

In the figures which illustrate example embodiments of the invention,

FIG. 1 to FIG. 29 illustrate aspects of the thin film transistors.

### DETAILED DESCRIPTION

Disclosed here is the design of a new vertical thin film transistor (VTFT) using hydrogenated amorphous silicon (a-Si:H) technology. This design allows the channel length to be scaled down to nanometer-scale (100 nm and beyond) as well as the smallest possible TFT size on glass, plastic, or other common types of substrates, based on the standard photo-etching and thin film deposition processes [1],[2],[3],[4],[5]. The emphasis of using the standard processes for the new VTFTs has a strong implication that no additional process equipment and capital investments are required for technological advancements and gains in performance.

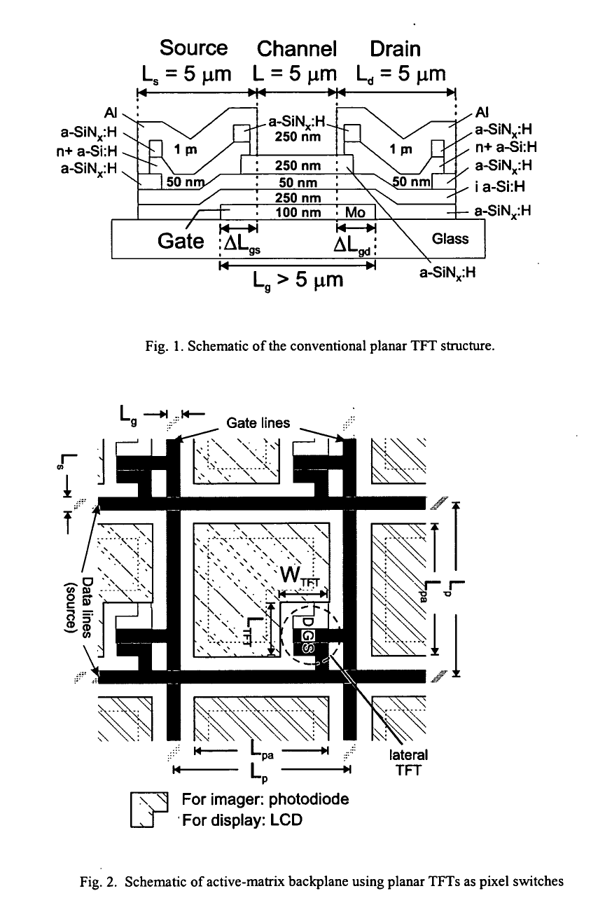

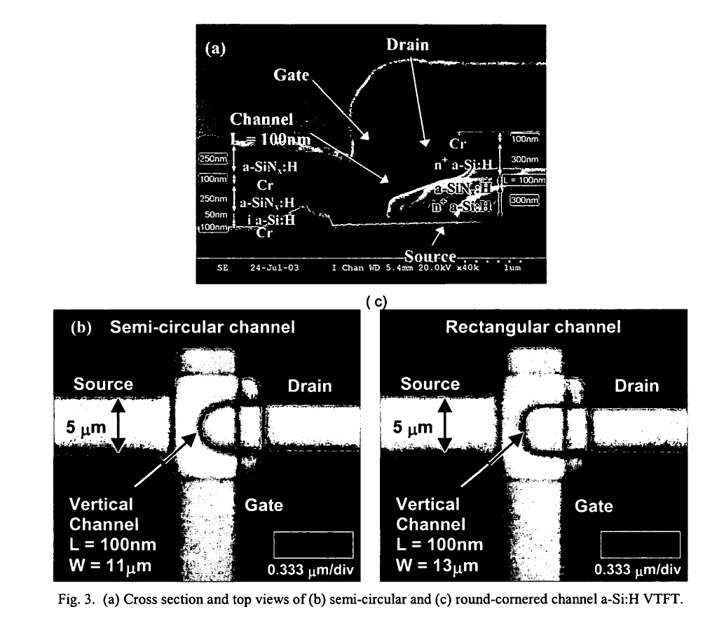

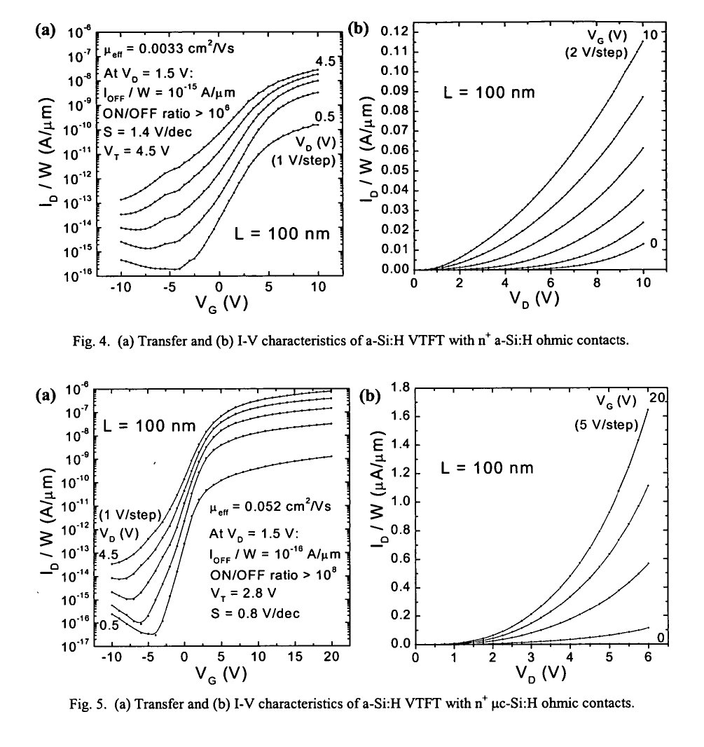

At the current state of art, lithographic technology is constrained to 5-μm or larger features [6] for large-area active-matrix imagers and displays, due to the stringent requirements of photo-etching precision and high yield on TFT and interconnect-line processes for virtually flawless images and low manufacturing cost. Consequently, advanced lithography for sub-micron to nano IC processes is usually not applicable to the production of large-area electronics. The TFT's channel length is therefore limited to about 5 μm and the overall TFT size, including the source, gate, and drain electrodes, is approximately triple of 5 μm in length and at least 10 μm in width (15×10 μm²), depending on the W/L ratio (see FIG. 1). However, when fabricating TFTs in vertical structure, the channel length is defined by film thickness rather than by lithographic resolution, thus it can readily be scaled down to sub-micron dimensions and beyond by precisely controlling the film deposition time. Furthermore, the vertically stacked drain, source, and gate electrodes can be arranged in a strategic way such that the whole TFT is contained in the intersectional area of the electrodes (5×5 μm²) using the same (5-μm) lithographic technology (please see FIG. 16 and FIG. 17 for schematic illustration and p. 9-10 for text description). This method yields the smallest possible TFT size for any given lithographic resolution, putting a significant novelty in this VTFT design. Presently, high ON-OFF current ratio (˜10⁸) and low leakage current (˜1 fA at V_{d}=1.5 V) for 100-nm channel length and 5×5 μm² area a-Si:H TFTs (see FIG. 3, FIG. 4, and FIG. 5) can be successfully demonstrated with this promising design. Prospective development of short-channel VTFTs with channel length down to 25 nm is recently in progress.

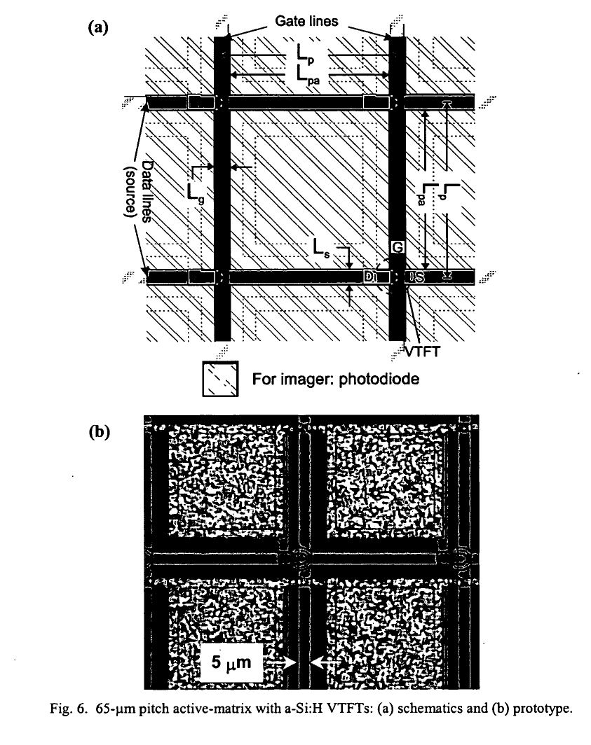

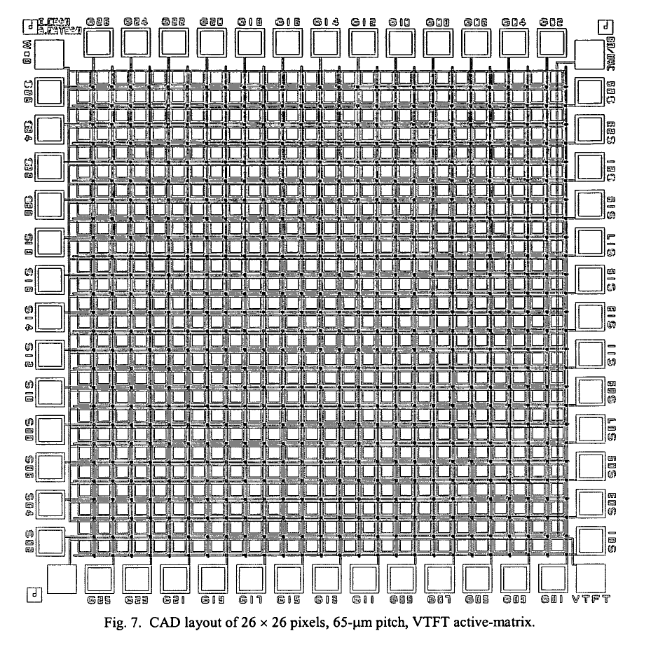

By integrating VTFTs with photodiode sensors, it can yield an immediate benefit to digital X-ray mammography, wherein the specified pixel pitch is of the order of 50 μm [7], to produce ample resolution for medical uses. In the traditional planar TFT design for pixelated active-matrix imagers, each TFT occupies part of the pixel area as a switch for the photo-sensor [8]. As a result, TFT size imposes a bottleneck to the array resolution, since the pixel fill factor, defined as the photosensitive area over the pixel area, rapidly diminished below sub-100 μm pixel pitch. The present solution to resolve this constraint on fill factor is by stacking up a continuous layer of photo-sensor on top of the TFT matrix [9]. However, since planar TFTs always occupy some pixel area, in additional to that by the gate and data lines, the smallest possible pixel size is ultimately limited by the TFT size in this modality. This motivates a new attempt to eliminate such constraint by integrating VTFTs into the active-matrix instead. FIG. 6 and FIG. 7 show how these VTFTs are implemented in an active-matrix format. The critical features of the VTFTs are hidden at the intersections of the gate and data lines, thus their size does not obstruct any substrate area for photodiode fabrication within the pixels. The resolution or pixel fill factor, is therefore completely independent of the TFT size, regardless of whether the photo-sensor architecture is pixelated or continuous, which adds another novelty in a system-level design. Based on 5-μm lithographic technology, the estimated fill factor for 50-μm pitch pixelated arrays built with VTFTs is 81%¹, as opposed to 37% with planar TFTs. Theoretically, this new design should also be compatible with active-matrix display applications without considerable technological constraints, and it is now under development.
Fill factor calculations are based on the equation from [9].

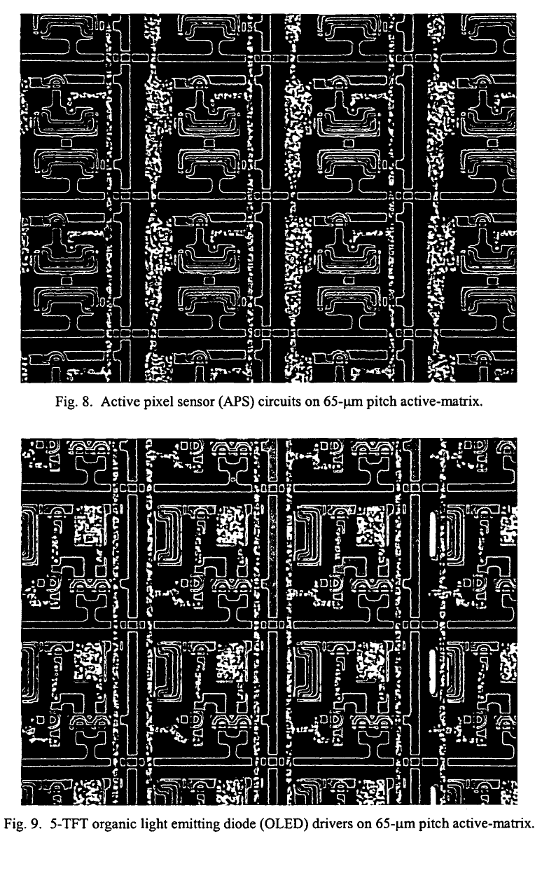

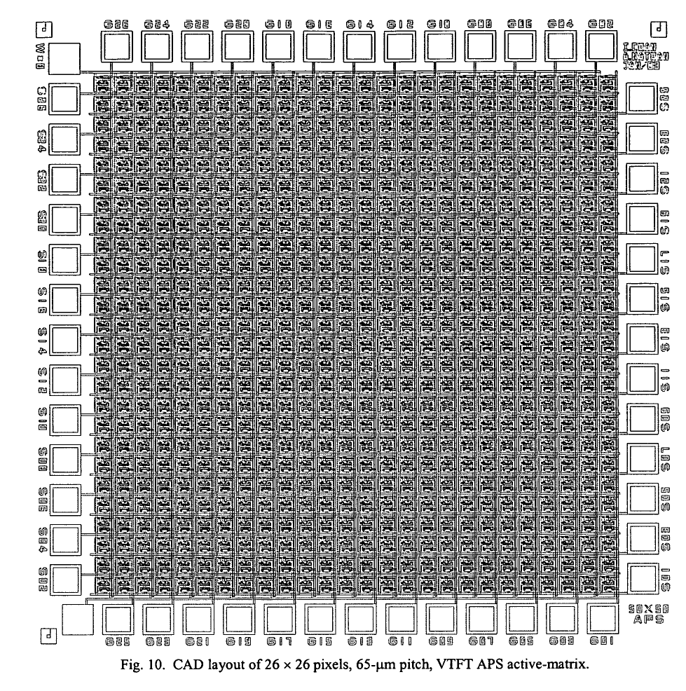

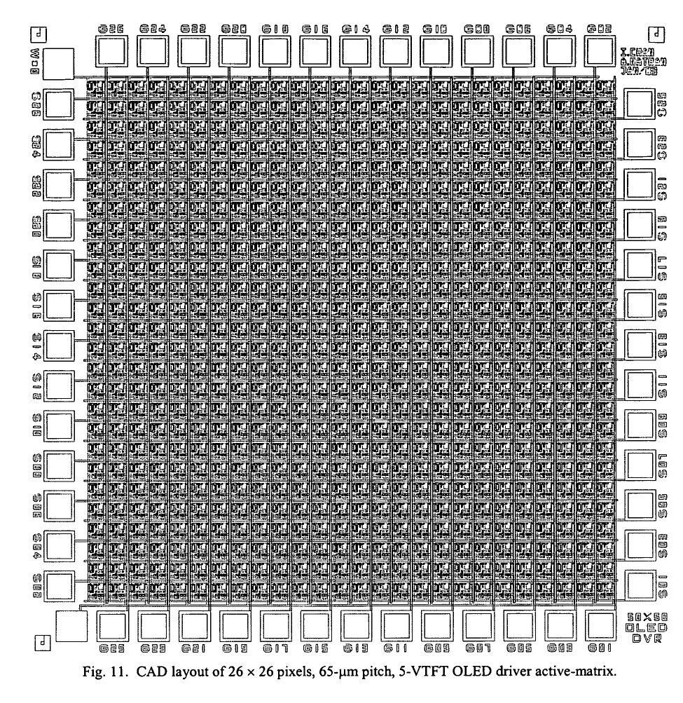

Such compact TFT concept can be further extended to the design of on-pixel circuitry to develop “smart” pixels without significant trade-offs in the image resolution. Examples of “smart” pixel concept include the active pixel sensor (APS) architecture for active-matrix imagers [10] and the five-TFT organic light emitting diode (OLED) driver for active-matrix displays [11]. The prototype for these pixel circuitries can be illustrated in FIG. 8, FIG. 9, FIG. 10, and FIG. 11. VTFT-based electronics are well suitable for electronic imaging and display applications that demand 50-μm pitch resolution and beyond at the present state of art or in the future, hence tremendous technological impacts are in sight.

### REFERENCES

[1] I. Chan, B. Park, A. Sazonov, and A. Nathan, ECS Proc., 63 (2000).
[2] I. Chan and A. Nathan, JVST A 20, 962 (2002).
[3] I. Chan and A. Nathan, MRS Symp. Proc. 715, 757 (2002).
[4] I. Chan and A. Nathan, to be published in JVST A (May/Jun 2004).
[5] I. Chan and A. Nathan, manuscript submitted to MRS Symp. Proc. (Apr 2004).
[6] T. Sandstrom and L. Odselius, SPIE 2621, 312 (1995).
[7] W. Zhao and J. A. Rowlands, Med. Phys. 22 (10), 1595 (1995).
[8] B. Park, Ph.D. thesis Ch. 6 p. 147, University of Waterloo (2001).
[9] J. T. Rahn et al., 1998 IEEE Nucl. Sci. Symp. Conf. Rec. 2, 1073 (1998).
[10] K. S. Karim et al., IEEE Trans. Elec. Dev. 50 (1), 200 (2003).
[11] P. Servati et al., JVST A 20 (4), 1374 (2002.).

### THE DEFINITION OF CURRENT INVENTION

Prior-Art Lateral TFT Structure:

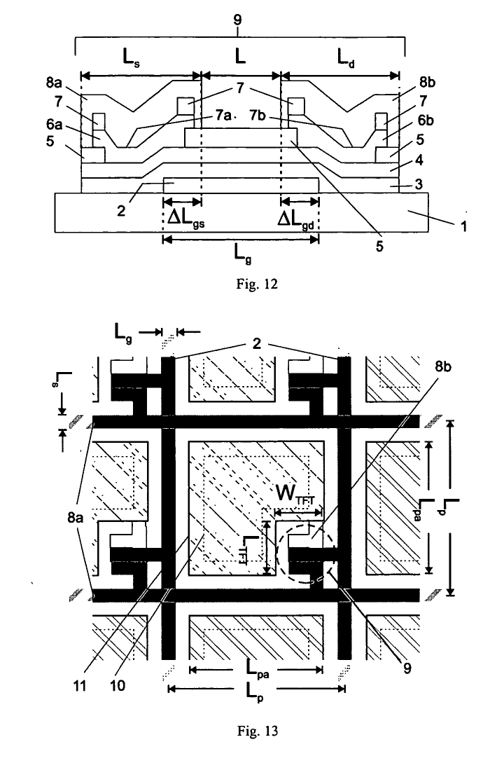

Thin film transistor (TFT) is a class of electronic switching device, which is commonly used in active-matrix flat-panel electronics, such as active-matrix liquid crystal display (AMLCD or sometimes called TFT-LCD) and optical/X-ray active-matrix flat-panel imagers (AMFPI). The core “active-matrix” technology for display and imaging is basically the same. This technology utilizes a two-dimensional (2-D) array of electronic active devices (TFTs), which are connected to the gate and data bus lines at their intersections, to selectively turn on and off the pixels to form a spatial display or sensing image. For imaging electronics, the pixels would be usually made up of p-i-n photodiodes as optical photodetectors connected to the pixel electrodes. Furthermore, X-ray detection can also be performed by adding a phosphor layer above the photodiodes to convert X-ray into optical photons for subsequent optical detection. For display electronics, those pixels would be made up of liquid crystals (LCs) connected to the pixel electrodes. The timing for TFT switching is controlled by peripheral circuit drivers, which are implemented by crystalline silicon complementary metal-oxide-semiconductor integrated circuits (CMOS ICs) with interfacing bond wires connected to the gate and data bus lines.
TFTs are good for active-matrix applications because the materials used in the manufacturing process, e.g. amorphous silicon (a-Si:H) and amorphous silicon nitride (a-SiNₓ:H), can be fabricated between 120 and 300° C., which is a thermal budget compatible with the commonly used substrate materials, e.g. glass and plastic, for active-matrix electronics.
Conventional TFT structure 9 (FIG. 12) is formed by a lateral (side-by-side) arrangement of source 8a, drain 8b, and gate 2 electrodes, where the distance (L) between the drain and source forms the transistor electron channel controlled by the gate voltage. The principle technology to form the electrode pattern and spacing is photolithography.
Referring to FIG. 12 for lateral TFT device fabrication, a metal film 2 (100-200 nm) such as molybdenum (Mo), chromium (Cr), or aluminum (Al), etc. is deposited by sputtering and patterned by conventional photolithography and etching as a gate electrode on a substrate 1 such as glass or plastic. Next, a consecutive deposition of the first insulating film 3, undoped semiconductor 4, and the second insulating film 5 to act as a gate dielectric (100-300 nm), active channel (50-300 nm), and the first passivation dielectric (100 - 300 nm) respectively is performed in one vacuum pump-down cycle to minimize the density of defect states at their interfaces. The gate dielectric 3 and first passivation dielectric 5 can be hydrogenated amorphous silicon nitride (a-SiNₓ:H) or hydrogenated amorphous silicon oxide (a-SiOₓ:H), etc. deposited by plasma enhanced chemical vapor deposition (PECVD). The undoped semiconductor 4 is usually hydrogenated amorphous silicon (a-Si:H) by PECVD. After the first passivation dielectric 5 is patterned to define the source 5a and drain 5b ohmic contact regions, an impurity-doped semiconductor film such as n⁺ a-Si:H (50-100 nm) and the third insulating film 7 (100-300) of the abovementioned materials are consecutively deposited and patterned to form source 6a and 6b drain ohmic contacts with the undoped semiconductor 4. Here, the third insulating film 7 acts as the second passivation dielectric for the impurity-doped semiconductor film. n⁺ microcrystalline silicon (n⁺ μc-Si:H) can also be used as ohmic contact layer for lower contact resistance. Next, the second passivation dielectric 7 is patterned with source 7a and drain 7b contact windows and followed by the deposition and patterning of a highly conductive metal such as Al to form the source 8a and drain 8b electrodes (100-1000 nm) to complete the lateral TFT structure 9. Note that the separation distance between the source 5a and drain 5b ohmic contact regions defines the channel length (L) by photolithography. Since certain lithographic alignment margins must be provided between masking steps to ensure 100% process yield, there will be overlapping regions between the gate and the source (ΔL_{gs}) and between the gate and the drain (ΔL_{gd}).
An active-matrix backplane configuration depicted in FIG. 13 is suitable for both AMLCD and optical/X-ray AMFPI. A lateral TFT 9, gate lines 2 and data lines 8a, TFT's drain and pixel electrodes 8b together can be fabricated by the aforementioned steps except for one difference on the material and processing for the pixel electrodes between the two applications. For AMFPI, the pixel electrodes can be any opaque metal such as Mo, Cr, Al, and so on, since the photodiodes are exposed to optical photons from the top of the panel. However, for AMLCD, the pixel electrodes must be a transparent conductor, such as indium tin oxide (ITO), since they must allow a backlight to transmit through them with the overall pixel transmittance modulated by the liquid crystal molecules. Since the pixel electrode material 8b (ITO) is different from the material for the data lines 8a, the process is slightly modified as follows. After the source 6a and drain 6b ohmic contacts are patterned, only the source contact window 7a and the source metal 8a (data lines) are patterned first, then the drain contact window 7b and the transparent conductor 8b for the drain and the pixel electrode are subsequently patterned. After the pixel electrodes 8b are formed, the entire active-matrix backplane is passivated by a dielectric layer patterned with contact windows 10. Finally, for AMFPI, photodiodes 11 are deposited and patterned above the pixel electrodes 8b. For AMLCD, the same 11 would be liquid crystals instead.
The first drawback of the lateral TFT structure 9 (FIG. 12) is that the channel length (L), which should be downward scalable to increase the switching speed and drive current of TFT is limited by the precision in photolithography to about 5 μm by the current flat-panel display industry standard. So TFT switching performance is constrained by the precision in photolithography that undermines the use of a-Si:H TFTs in building peripheral circuitry for driving the active-matrix backplane. As a result, crystalline silicon CMOS ICs interfacing bond wires are needed to implement the peripheral drivers, which would increase the manufacturing cost of active-matrix electronics.
The second drawback is that there are parasitic gate-to-source and gate-to-drain overlap capacitances (C_{gs} and C_{gd}) formed due to the inevitable lithographic alignment margins between gate 2 and source 8a ΔL_{gs} and between gate 2 and drain 8b ΔL_{gd}.
The third drawback is that since the structure is lateral, the TFT size would be large. This is particularly disadvantageous when it is used as a pixel switch in an active-matrix backplane (FIG. 13) because part of the pixel area is occupied by the large TFT, thus the fill factor (photosensitive area over total pixel area) of the imager pixels or the aperture ratio (illuminative area over total pixel area) of the display pixels are greatly reduced, as defined by the following expression:

$$f = \frac{{( {L}_{p} - {L}_{pa} )}^{2} - ( {L}_{TFT} \cdot {W}_{TFT} )}{{L}_{p}^{2}} .$$

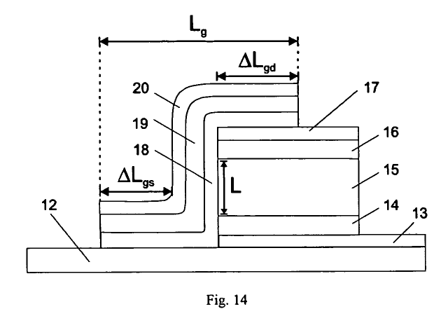

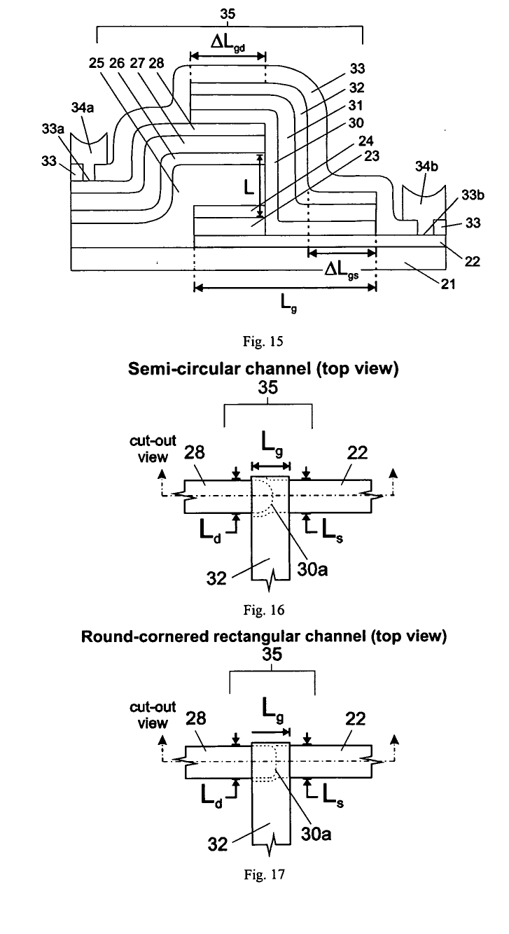

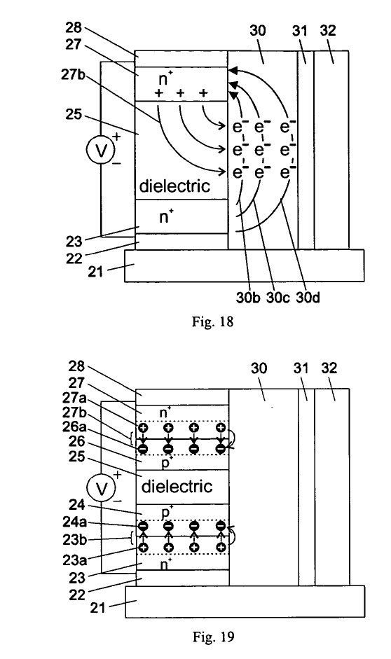

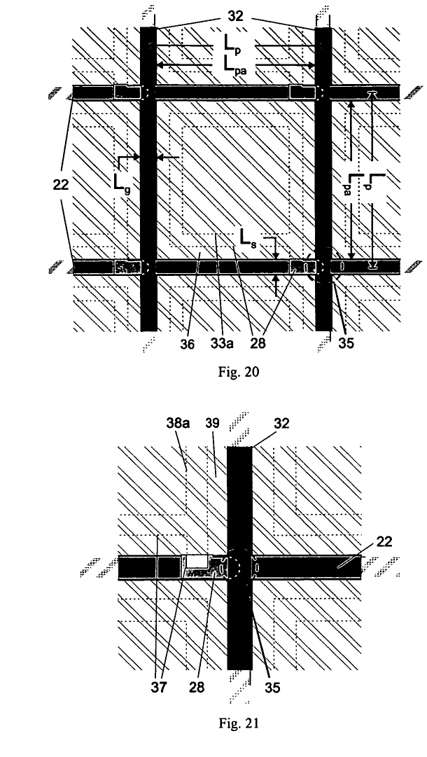

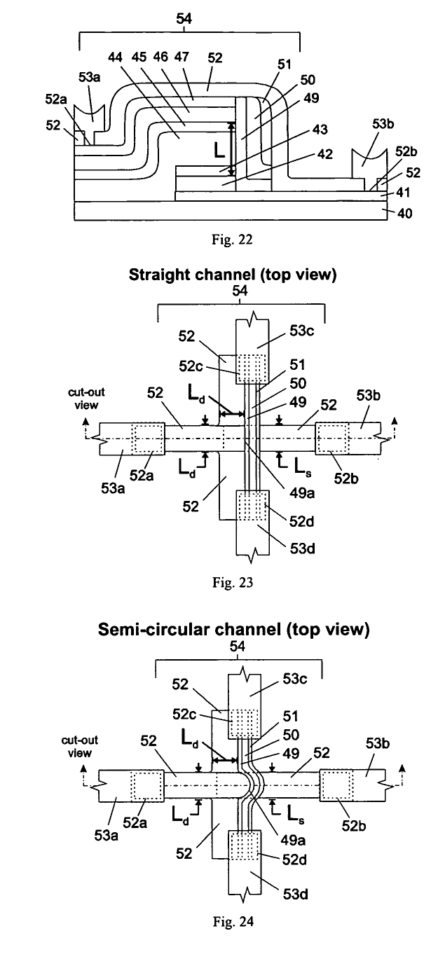

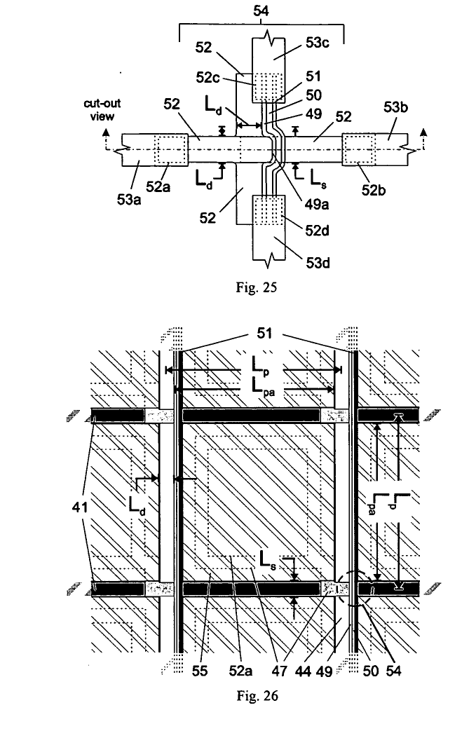

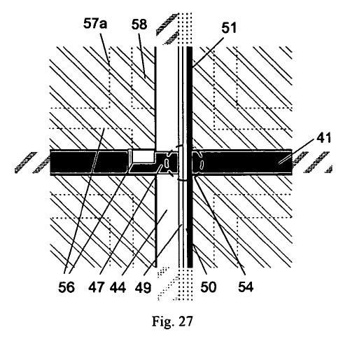

Prior-Art Vertical TFT Structure:
In the article, Uchida et al. IEEE Electron Device Lett., EDL-5 (4), 105 (1984), a vertical TFT (VTFT) cross-sectional structure (FIG. 14) was proposed to eliminate the use of photolithography to define the channel length (L), but use a dielectric (a-SiNₓ:H) film 15 thickness and reactive ion etching to form a channel in the vertical direction. Since dielectric film thickness can be easily and precisely controlled by deposition time to 1 μm or less, a TFT with submicron channel length is easily achievable by this structure, which has a significant switching speed improvement over the lateral TFT counterpart. Therefore, it allows building peripheral circuitry directly on the panel to replace CMOS ICs and interfacing overheads and thereby reduce manufacturing cost.
Refering to FIG. 14 for a prior-art vertical TFT device fabrication, the deposition of source metal film 13 (100-200 nm), source impurity doped semiconductor film 14 (100-300 nm), channel-defining dielectric 15 (25-1000 nm), drain impurity doped semiconductor film 16 (100-300 nm), and the drain metal film 17 (100-200 nm) are performed, which are then patterned to form a drain-source multi-layered structure on a glass or plastic substrate 12. The metal films 13 and 17 can be Mo, Cr, or Al, etc., impurity doped semiconductor films 14 and 16 can be n⁺a-Si:H or n⁺ μc-Si:H, and the dielectric 15 can be a-SiNₓ:H or a-SiOₓ:H. While the metal films 13 and 17 can be patterned by wet chemistry, the doped semiconductor and dielectric films 14, 15, and 16 must be patterned by anisotropic reactive ion etching (RIE). Suitable gases for RIE are CF₄/H₂, CHF₃, CF₃Cl, etc. Next, undoped semiconductor 18 (50-300 nm), gate dielectric 19 (50-300 nm), and gate metal 20 (100-300 nm) are deposited and patterned to form the vertical gate and channel. The materials for 18, 19, and 20 can be undoped a-Si:H, a-SiNₓ:H, and Al, respectively. Note that the channel length (L) is defined by the dielectric film 15 thickness. Finally, some area of Layers 17, 16, 15, and 14 are etched away to expose the source electrode 13 for metal interconnection.
The first drawback of this cross-sectional VTFT structure is that it does not address the TFT size issue in lateral TFTs for flat-panel electronics. Although it is generally understood that a TFT in vertical structure should occupy less area than a TFT in lateral structure, this implies that it would just occupy less pixel area. It would be the best to seek for the ultimate solution, of which the VTFT can be designed in a particular structure so that it is hidden at the gate and data lines and therefore it does not occupy any pixel area.
The second drawback is the inherently large gate-to-source and gate-to-drain overlap (ΔL_{gs} and ΔL_{gd}) capacitances of this cross-sectional structure, which is also a limiting factor for high speed switching, since the switching time delay is proportional to both the channel length and gate input capacitance.
The third drawback is that this cross-sectional structure does not provide a way to scale up the channel width, which is another parameter to increase the drive current, because it can only be controlled in the lateral dimension (top view) of the VTFT and the merit of this VTFT is only on the capability of submicron channel length scalability by the cross-sectional structure. Since the top-view structure is not investigated, the capability of channel width scalability is unknown.
The fourth drawback is that it does not provide a method to suppress short-channel effects, which is common to all field effect transistors (CMOS or TFT) with channel length of 1 μm or less. At least 3 short-channel effects can be identified with this structure as illustrated in FIG. 18: “back-gate” effect 30b, space-charge-limited current (SCLC) 30c, and drain induced charge accumulation 30d. The “back-gate” effect 30b occurs due to a back-interface electron channel induced by the capacitive coupling 27b between the drain n⁺ 27 and the undoped a-Si:H channel region 30. SCLC 30c is also possible since the conduction of the trapped space charge through the bulk undoped a-Si:H 30 increases as the drain-to-source electrode spacing decreases or the drain voltage increases. Drain induced charge accumulation 30d, which is analogous to drain induced barrier lowering (DIBL) in crystalline Si MOSFETs, can happen since the drain electric field accumulates electrons at the tail states of a-Si:H 30 at the front interface and thereby induces higher drain current. These adverse effects should be suppressed to ensure high performance of the VTFT.
   New VTFT Structure (Current Invention):
   Objectives of Current Invention
To provide a VTFT structure in a specific electrode arrangement such that the lateral TFT size on substrate is the smallest for any given lithographic technology. Since the smallest patternable area by any given lithography is the intersectional area of the minimum patternable linewidth, hence providing a VTFT structure that can be formed entirely within this area is the smallest. For any better lithographic resolution available in the future, this VTFT structure can still be realized in the smallest size by the new technology standard. For example, if the lithographic technology used is 5 μm, the smallest VTFT size is 5×5 μm². If the technology is advanced to 1 μm, the VTFT size would be 1×1 μm². This trend will follow until the VTFT size is so small that the performance is prevailed by quantum mechanical effects.
To provide a VTFT structure which allows the scale-up of the channel width by controlling the perimeter dimension of the drain electrode through changing the perimeter geometry, but without changing the TFT size.
To provide a VTFT structure that can suppress the short-channel effects in VTFT electrical characteristics.
To provide a VTFT structure that can be incorporated into active matrix electronics as pixel switches.
To provide a VTFT structure, when used in flat-panel electronics, not just with a smaller size than the lateral TFTs to improve fill factor (or aperture ratio), but in a special arrangement such that the entire VTFT structure is hidden within the intersectional area of the gate and data lines to maximize the fill factor (or aperture ratio). In other words, the fill factor (or aperture ratio) becomes truly TFT size independent.
To provide a VTFT structure that is also compatible with the existing continuous photosensor approach to achieve 100% fill factor.
To provide a VTFT structure that has the smallest TFT size such that it can be used to build circuitry within the pixel area without significant tradeoff with the fill factor (or aperture ratio).
To provide a modification of the new VTFT structure such that the gate electrode is completely vertical and located only on the sidewall of the vertical channel structure. This way can eliminate the gate-to-source and gate-to-drain lateral overlap capacitances due to constraints in photolithography, including the abovementioned objectives.
To provide this modification of the new VTFT structure in a way that is accessible by metal line interconnection.
   Summary of the Current Invention
To accomplish the above objects, a new VTFT structure 35 is disclosed here (cross-section in FIG. 15 and top-views of two selected channel geometries in FIG. 16 and FIG. 17). First of all, the source 22 and drain 28 electrodes are patterned in parallel but only overlapping at their ends with extensions to the opposite directions, then the gate 32 electrode is patterned in orthogonal direction to form an intersection with the former two electrodes at their overlapping region, where the VTFT structure 35 is formed. It is achievable by this design because all electrodes are patterned by separate mask steps to allow layout flexibility of forming VTFT at their intersection only with the least drain-source overlapping area. Therefore, the VTFT size is the smallest by its architecture. Whether the prior-art VTFT structure 14 can form the smallest TFT is unknown, and it does not have the flexibility to form the drain-source overlapping area only at the ends of the drain 17 and source 13 electrodes since the drain-source multi-layered structure is formed by one mask step, not separately by two mask steps.
A unique method of channel width scaling is also illustrated in FIG. 16 and FIG. 17. Two channel geometries 30a, semi-circular and round-cornered rectangular, are selected to demonstrate the concept. Since the channel width is defined by the perimeter dimension of the drain electrode 28, it is scalable by only changing the channel geometry while keeping the TFT size exactly the same.
To suppress the short-channel effects 30b, 30c, 30d that usually appears in submicron channel TFTs (as well as in crystalline Si MOSFETs), a sandwiched structure of p⁺/dielectric/p⁺ 24, 25, 26 (FIG. 15) is used instead of a single channel-defining dielectric 25. This structure is analogous to the halo doping in crystalline Si CMOS technology. For clarity, the VTFT schematic in FIG. 15 is redrawn in a generic schematic in FIG. 19 to illustrate the mechanisms for suppressing short-channel effects. Since There are internal electric fields 23b, 27b built up at the junctions between p⁺ 24, 26 and n⁺ 23, 27. Increasing drain voltage bias would only change these internal fields 23b, 27b by varying the immobile space charge regions 26a, 27a and 23a, 24a. As a result, the drain and source fields 23b, 27b are more confined in the p-n junctions and thereby suppressing the short-channel effects 30b, 30c, 30d.
FIG. 20 shows the configuration of the active-matrix for AMFPI using the new VTFTs 35 as pixel switches. Since the smallest VTFT can be fabricated within the intersectional area of the electrodes, that means a plurality of VTFT pixel switches 35 can be completely hidden at the intersections of the active-matrix. Therefore, they do not obstruct any pixel area for the photodiodes. Photodiode area 36 (hatched area) can be extended to the boundaries of the grid lines to maximize the pixel fill factor for pixelated imaging array. In other words, the fill factor becomes truly TFT size independent.
The concept is basically the same for both AMFPI and AMLCD applications except that the pixel electrode 28 for the former (FIG. 20) can be any suitable opaque metal such as Mo, Cr, or Al etc. while the same 37 for the latter (FIG. 21) must be a transparent conductor such as ITO and the hatched area would be for liquid crystals 39 instead.
For AMFPI, this invention also allow the photodiode 36 to be a continuous structure instead of being patterned into a discretized array of photodiodes in order to achieve 100% fill factor.
To minimize the gate-to-source and gate-to-drain overlap (ΔL_{gs} and ΔL_{gd}) capacitances, the VTFT structure 35 is modified into another VTFT structure with fully non-overlapping vertical gate 54 (FIG. 22). Here, the undoped semiconductor 49, gate dielectric 50, and gate metal 51 do not have any lateral overlaps with the source 41 and drain 47 electrodes, thus overlap capacitances are minimized.
The top views (FIG. 23, FIG. 24, FIG. 25) of this modified VTFT structure 54 shows how the fully vertical gate structure 51 can be accessible by metal interconnections 53c and 53d. The vertical gate 51 is extended away from the critical area of the VTFT, thus metal interconnections 53c and 53d can be formed without imposing practical issues on the integrity of the VTFT structure 54. The top views also show that channel width scaling by channel geometry in the original VTFT structure 35 is also fully applicable to the modified VTFT structure 54.
FIG. 26 shows the configuration of the active-matrix for AMFPI using the modified VTFTs 54 as pixel switches. The fill factor here is also TFT size independent as using the original VTFTs as pixel switches FIG. 20.
Same ideas are fully applicable to AMLCD except that that the pixel electrode 47 for the former (FIG. 26) can be any suitable opaque metal such as Mo, Cr, or Al etc. while the same 56 for the latter (FIG. 27) must be a transparent conductor such as ITO and the hatched area would be for liquid crystals 58 instead.

### THE MANUFACTURE OF VERTICAL THIN FILM TRANSISTOR

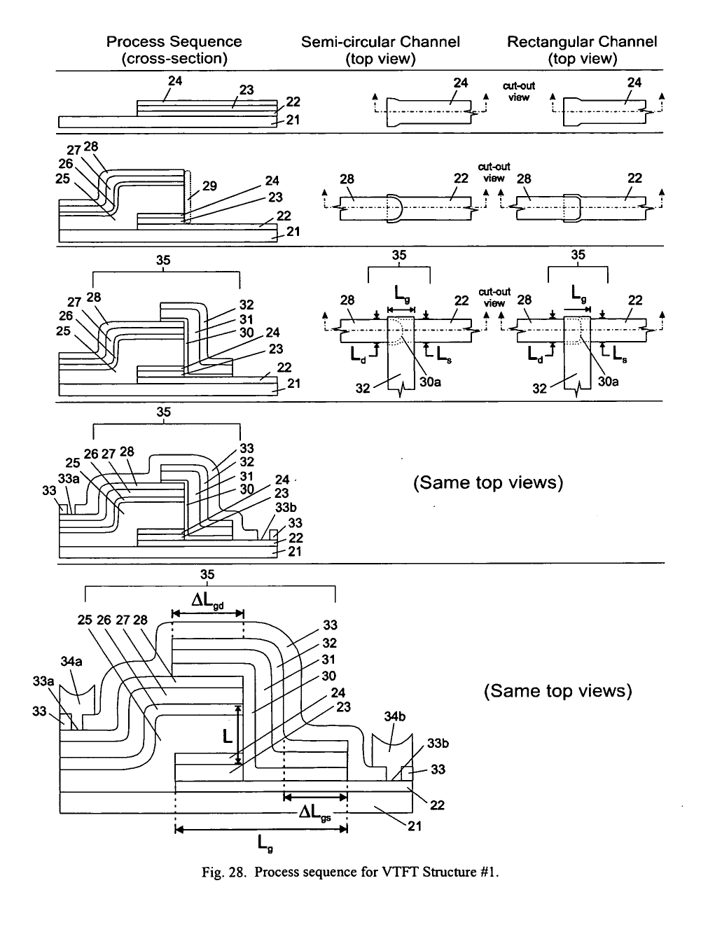

### VTFT Structure #1 (see FIG. 28)

Detailed Process Descriptions:

Mask 1

The VTFT process starts with a glass, plastic, or other common types of substrates 21 that are designed for use in the manufacture of active-matrix flat-panel electronics. First, a non-refractory metal film 22, such as chromium (Cr) or aluminum (Al), is deposited onto the substrate at room temperature, usually by sputter deposition or evaporation techniques, for use as the bottom (source) electrode. Thickness of this metal film is typically 100 nm, but not critical. Then, a heavily doped n-type semiconductor film 23, such as hydrogenated amorphous silicon (n⁺ a-Si:H), micro-crystalline silicon (n⁺ μc-Si:H), or polysilicon (n⁺ poly-Si), is deposited onto the bottom (source) metal film to act as the source ohmic contact layer. In the case of n⁺ a-Si:H and n⁺ μc-Si:H for an n-channel VTFT, it can usually be deposited by plasma enhanced chemical vapor deposition (PECVD) technique. n⁺ poly-Si can be made by ELA processing of the n⁺ a-Si:H film. Other techniques are also capable of and readily available for n⁺ a-Si:H, n⁺ μc-Si:H, and n⁺ poly-Si film fabrication. This ohmic contact material is preferably, although not necessarily, made of μc-Si:H due to its higher electrical conductivity than a-Si:H, yet require simpler process conditions than poly-Si. However, in terms of electrical conductivity, poly-Si is the highest of the said ohmic contact materials and can be used when manufacture complication is not a big issue. This ohmic contact film 23 thickness can be in the range from 100 to 300 nm without causing serious issues in the substrate topography. After that, a heavily doped p-type semiconductor film 24 (5-20 nm), such as p⁺ a-Si:H, is deposited usually by PECVD to be a short-channel effect (SCE) suppression layer for the source.

A photomask is used in photolithography to define a photoresist pattern, which is then used as a mask for the subsequent etching to form the bottom (source) electrode. Wet etching or plasma etching, particularly reactive ion etching (RIE), can be used for etching the p⁺ layer 24 and the n⁺ ohmic contact layer 23. Wet etchant can be potassium hydroxide (KOH) solution, while plasma etchant can be a fluorine-based plasma (e.g. CF₄, CF₄/H₂, CHF₃), chlorine-based plasma (e.g. CF₃Cl, CCl₄, BCl₃), or a bromine-based plasma (e.g. HBr, CF₃Br) with appropriate vacuum process conditions. Reactive ion etching (RIE) is a more favorable etching technique simply because of its anisotropic (directional) nature for better linewidth control, but precision on anisotropy is not important. For the Cr film underneath the patterned n⁺ a-Si:H or n⁺ μc-Si:H film, it can be etched by Cr wet etchant (Ce(NH₄)₂(NO₃)₆+CH₃COOH +H₂O) or chlorine-based plasma. If the electrode material is Al instead, another wet etchant (H₂PO₃+CH₃COOH+HNO₃+H₂O) or the same plasma etchant can be used for etching. Finally, the photoresist is stripped away by a conventional stripper solution or an oxygen-based plasma (e.g. O₂, O₂/CF₄) for the next film deposition sequence.

Mask 2

A dielectric film 25, such as hydrogenated amorphous silicon nitride (a-SiNₓ:H) or oxide (a-SiOₓ:H), is deposited by PECVD to act as a channel-defining dielectric between the source and drain. Its thickness must be precisely controlled by the deposition time to accurately define the channel length (L) in submicron or sub-100 nm dimensions. Typically, the thickness of this dielectric film can be practically controlled from 25 to 1000 nm. A p-type semiconductor film 26 (5-20 nm), such as p⁺ a-Si:H, is deposited to be another SCE suppression layer for the drain. Next, another 100-300 nm n⁺ a-Si:H, μc-Si:H, or poly-Si 27 is deposited by the same method as the drain ohmic contact. Another 100-200 nm non-refractory metal (Cr or Al) film 28 is deposited subsequently as the top (drain) electrode.

Using photoresist as a mask, the metal/n⁺/p⁺/dielectric/p⁺/n⁺ multi-layered structure 28, 27, 26, 25, 24, 23 is etched accordingly to form the top (drain) electrode pattern as well as the vertical structure. Note that the channel geometry 30a can be semi-circular or round-cornered rectangular, as seen from the top view. These geometries are purposely designed for channel width scalability while keeping the TFT size exactly the same. The top metal film 28 can be etched either by wet or plasma etchants but the underlying layers 27, 26, 25, 24, 23 must be etched by RIE. The top metal film 28 can be used as a self-aligned mask for this RIE process. The anisotropy of the RIE process must be carefully controlled to give a highly vertical profile 29 for the reliability of the later film deposition processes. For example, if this multi-layered structure is formed with a zig-zag profile, due to a poorly controlled RIE process, subsequent film deposition processes will be very difficult to give a reliable step coverage to form an electrically conductive channel and gate electrode vertically. Thus, the VTFT becomes non-functional.

Mask 3

An undoped semiconductor film 30, such as undoped a-Si:H, μc-Si:H, or poly-Si, is deposited onto the vertical structure by PECVD to serve as an active channel material. The thickness should be thin of the order of 50 nm to reduce the leakage current due to space-charge-limited current (SCLC) during the VTFT's off-state. SCLC is a bulk effect and can be effectively suppressed by reducing the film thickness. Then, an a-SiNₓ:H or a-SiOₓ:H gate dielectric film 31 and a 100-300 nm non-refractory metal (Cr or Al) gate film 32 are sequentially deposited and patterned using photoresist to form the vertical gate electrode. Gate dielectric film 31 thickness should be scaled accordingly with the channel length to provide sufficient gate control of the channel, but are roughly in the range of 25 to 250 nm. Alternatively, high-k gate dielectric like Ta₂O₅ may be used to obtain high drive current with thicker dielectric to avoid high gate leakage current due to tunneling phenomena. The etching process in this case should be isotropic (non-directional) because the unmasked portion of the gate materials on the sidewall surfaces can only be etched by lateral etching. Wet etching techniques can be used here because of the isotropic nature of chemical etching. Isotropic plasma etching can also be use to achieve the same purpose. Isotropic etching can be achieved by operating the RIE process in the isotropic regime. Other plasma excitation methods, such as inductively coupled plasma (ICP), can also be used to enhance the isotropy. After this, the VTFT structure is completed. The last two masks are for device passivation and final metallization or interconnections.

Mask 4

Usually, a 100-300 nm a-SiNₓ:H or a-SiOₓ:H dielectric film 33 is deposited on the VTFT structure by PECVD to serve as a passivation layer for electrical isolation and an etch-stop layer for final metallization or interconnections. In some cases, low-k dielectric materials, such as benzocyclobutene (BCB) liquid-based photopolymer, are desirable to reduce capacitive coupling between metal lines as well as serving as a planarization layer to minimize substrate topography. The process technology for BCB is basically the same as photoresist lithography. At a certain distance away from the VTFT critical features, the passivation dielectric film is patterned with contact windows 33a and 33b to uncover the top (drain), bottom (source), and vertical gate electrodes for making electrical connection with the final metal or interconnections. Wet or plasma etchants are well suitable for this task.

Mask 5

A highly conductive metal film, such as aluminum (Al), is deposited by sputter deposition or evaporation to function as the final metal or interconnections. This film is between 100 nm and 1 μm, depending on the design of the electrical resistance and the manufacturing process requirements. Wet or plasma etchant can be used to pattern the Al film into structures 34a and 34b to complete the VTFT device fabrication.

Modifications for Active-Matrix Backplane Integration

In active-matrix backplane integration, the manufacturing process for the VTFT array is slightly different from the process for a single device. The process for AMFPI backplane (FIG. 20) is completed at Mask 4 (insulating film passivation) step. The hatched areas 36 in FIG. 20 are the areas for the photodiodes.

For AMLCD backplane (FIG. 21), however, one extra material and photomask step between Mask 3 and 4 are needed to form a transparent pixel electrode 37. This transparent pixel electrode 37 is usually indium tin oxide (ITO) with a typical thickness of 100 nm. HCl solution can be used to etch ITO and pattern the pixel electrode structure. After that, passivation dielectric and contact windows 38a are deposited and patterned, respectively, to complete the process. The hatched areas 39 in FIG. 20 are the areas for the liquid crystal. Therefore, totally 5 photomask steps are needed for AMLCD backplane.

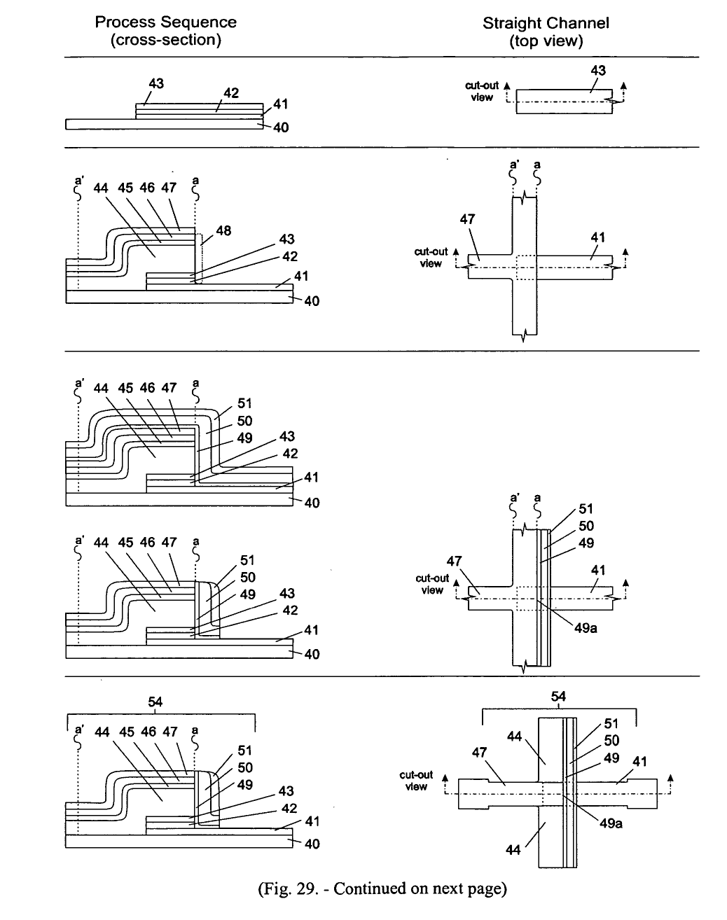

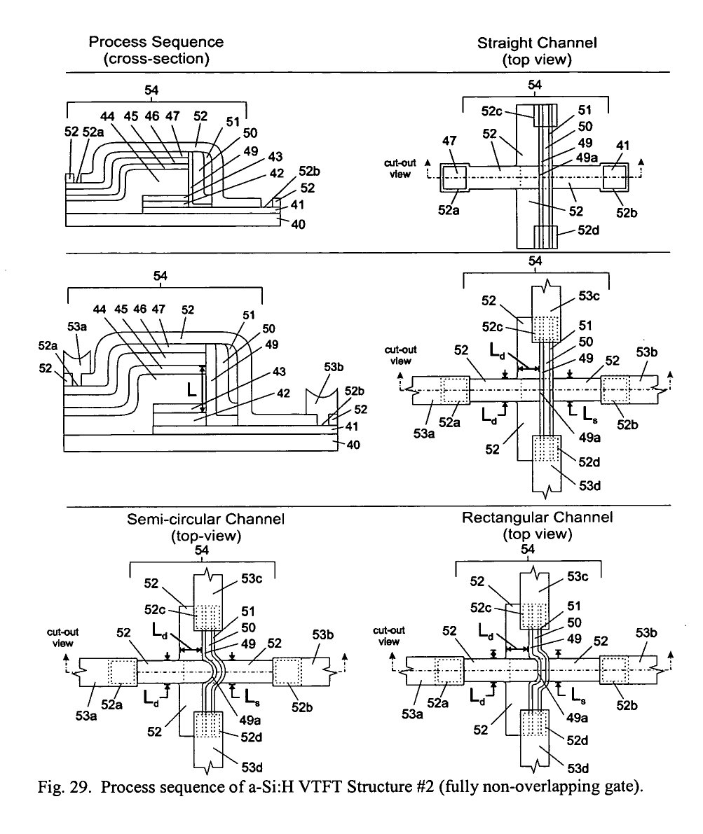

VTFT Structure #2 (see FIG. 29)

Detailed Process Descriptions:

Mask 1

The VTFT process starts with a glass, plastic, or other common types of substrates 40 that are designed for use in the manufacture of active-matrix flat-panel electronics. First, a non-refractory metal film 41, such as chromium (Cr) or aluminum (Al), is deposited onto the substrate at room temperature, usually by sputter deposition or evaporation techniques, for use as the bottom (source) electrode. Thickness of this metal film is typically 100 nm, but not critical. Then, a heavily doped n-type semiconductor film 42, such as hydrogenated amorphous silicon (n⁺ a-Si:H), micro-crystalline silicon (n⁺ μc-Si:H), or polysilicon (n⁺ poly-Si), is deposited onto the bottom (source) metal film to act as the source ohmic contact layer. In the case of n⁺ a-Si:H and n⁺ μc-Si:H for an n-channel VTFT, it can usually be deposited by plasma enhanced chemical vapor deposition (PECVD) technique. n⁺ poly-Si can be made by ELA processing of the n⁺ a-Si:H film. Other techniques are also capable of and readily available for n⁺ a-Si:H, n⁺ μc-Si:H, and n⁺ poly-Si film fabrication. This ohmic contact material is preferably, although not necessarily, made of μc-Si:H due to its higher electrical conductivity than a-Si:H, yet require simpler process conditions than poly-Si. However, in terms of electrical conductivity, poly-Si is the highest of the said ohmic contact materials and can be used when manufacture complication is not a big issue. This ohmic contact film 42 thickness can be in the range from 100 to 300 nm without causing serious issues in the substrate topography. After that, a heavily doped p-type semiconductor film 43 (5-20 nm), such as p⁺ a-Si:H, is deposited usually by PECVD to be a short-channel effect (SCE) suppression layer for the source.

A photomask is used in photolithography to define a photoresist pattern, which is then used as a mask for the subsequent etching to form the bottom (source) electrode. Wet etching or plasma etching, particularly reactive ion etching (RIE), can be used for etching the p⁺ layer 43 and the n⁺ ohmic contact layer 42. Wet etchant can be potassium hydroxide (KOH) solution, while plasma etchant can be a fluorine-based plasma (e.g. CF₄, CF₄/H₂, CHF₃), chlorine-based plasma (e.g. CF₃Cl, CCl₄, BCl₃), or a bromine-based plasma (e.g. HBr, CF₃Br) with appropriate vacuum process conditions. Reactive ion etching (RIE) is a more favorable etching technique simply because of its anisotropic (directional) nature for better linewidth control, but precision on anisotropy is not important. For the Cr film underneath the patterned n⁺ a-Si:H or n⁺ μc-Si:H film, it can be etched by Cr wet etchant (Ce(NH₄)₂(NO₃)₆+CH₃COOH+H₂O) or chlorine-based plasma. If the electrode material is Al instead, another wet etchant (H₂PO₃+CH₃COOH+HNO₃+H₂O) or the same plasma etchant can be used for etching. Finally, the photoresist is stripped away by a conventional stripper solution or an oxygen-based plasma (e.g. O₂, O₂/CF₄) for the next film deposition sequence.

Mask 2

A dielectric film 44, such as hydrogenated amorphous silicon nitride (a-SiNₓ:H) or oxide (a-SiOₓ:H), is deposited by PECVD to act as a channel-defining dielectric between the source and drain. Its thickness must be precisely controlled by the deposition time to accurately define the channel length (L) in submicron or sub-100 nm dimensions. Typically, the thickness of this dielectric film can be practically controlled from 25 to 1000 nm. A p-type semiconductor film 45 (5-20 nm), such as p⁺ a-Si:H, is deposited to be another SCE suppression layer for the drain. Next, another 100-300 nm n⁺ a-Si:H, μc-Si:H, or poly-Si 46 is deposited by the same method as the drain ohmic contact. Another 100-200 nm non-refractory metal (Cr or Al) film 47 is deposited subsequently as the top (drain) electrode.

Using photoresist as a mask, the metal/n⁺/p⁺/dielectric/p⁺/n⁺ multi-layered structure 47, 46, 45, 44, 43, 42 is etched accordingly to form the top (drain) electrode pattern as well as the vertical channel structure. Note that the top (drain) electrode 47 is formed in a “T” structure so that a fully non-overlapping vertical gate electrode can be formed on this “T” structure in the later steps. In the subsequent masking steps, the channel width will be defined at the edge where the “T”-shaped top (drain) electrode overlaps with the bottom (source) electrode. Also note that the channel geometry 49a can be straight, semi-circular or round-cornered rectangular, as seen from the top view. These geometries are purposely designed for channel width scalability while keeping the TFT size exactly the same. The top metal film 47 can be etched either by wet or plasma etchants but the underlying layers 46, 45, 44, 43, 42 must be etched by RIE. The top metal film 47 can be used as a self-aligned mask for this RIE process. The anisotropy of the RIE process must be carefully controlled to give a highly vertical profile 48 for the reliability of the later film deposition processes. For example, if this multi-layered structure is formed with a zig-zag profile, due to a poorly controlled RIE process, subsequent film deposition processes will be very difficult to give a reliable step coverage to form an electrically conductive channel and gate electrode vertically. Thus, the VTFT becomes non-functional.

Mask 3

An undoped semiconductor film 49, such as undoped a-Si:H, μc-Si:H, or poly-Si, is deposited onto the vertical structure by PECVD to serve as an active channel material. The thickness should be thin of the order of 50 nm to reduce the leakage current due to space-charge-limited current (SCLC) during the VTFT's off-state. SCLC is a bulk effect and can be effectively suppressed by reducing the film thickness. Then, an a-SiNₓ:H or a-SiOₓ:H gate dielectric film 50 and a 100-300 nm non-refractory metal (Cr or Al) gate film 51 are sequentially deposited and patterned using photoresist to form the vertical gate electrode. Gate dielectric film 50 thickness should be scaled accordingly with the channel length to provide sufficient gate control of the channel, but are roughly in the range of 25 to 250 nm. Alternatively, high-k gate dielectric like Ta₂O₅ may be used to obtain high drive current with thicker dielectric to avoid high gate leakage current due to tunneling phenomena.

The non-refractory gate electrode 51 is etched by chlorine-based plasma. Since this plasma is highly selective against the usual gate dielectric material 50, e.g. a-SiNₓ:H or a-SiOₓ:H, thus the etch endpoint for the gate can be ensured. Then a photoresist mask (Mask 3) is applied here to pattern the gate electrode on the channel side with wet etching or isotropic chlorine-based plasma etching. After the photoresist is removed, another isotropic etching with wet or plasma chemistry can remove the gate dielectric 50 and undoped semiconductor 49 films.

Mask 4

This masking step enables the gate electrode 51 to be electrically isolated from the top (drain) electrode 47. A photoresist covers both the top (drain) 47 and the bottom (source) 41 electrodes, then the uncovered top (drain) metal 47, n⁺ ohmic contact layer 46, and p⁺ SCE suppression layer 45 are either etched by wet or plasma etchants. After this, the VTFT structure is completed. The last two masks are for device passivation and final metallization or interconnections.

Mask 5

Usually, a 100-300 nm a-SiNₓ:H or a-SiOₓ:H dielectric film 52 is deposited on the VTFT structure by PECVD to serve as a passivation layer for electrical isolation and an etch-stop layer for final metallization or interconnections. In some cases, low-k dielectric materials, such as benzocyclobutene (BCB) liquid-based photopolymer, are desirable to reduce capacitive coupling between metal lines as well as serving as a planarization layer to minimize substrate topography. The process technology for BCB is basically the same as photoresist lithography. At a certain distance away from the VTFT critical features, the passivation dielectric film is patterned with contact windows 52a, 52b, 52c, and 52d to uncover the top (drain) 47, bottom (source) 41, and vertical gate 51 electrodes for making electrical connection with the final metal or interconnections. Wet or plasma etchants are well suitable for this task.

Mask 6

A highly conductive metal film, such as aluminum (Al), is deposited by sputter deposition or evaporation to function as the final metal or interconnections. This film is between 100 nm and 1 μm, depending on the design of the electrical resistance and the manufacturing process requirements. Wet or plasma etchant can be used to pattern the Al film into structures 53a, 53b, 53c, and 53d to complete the VTFT device fabrication.

Modifications for Active-Matrix Backplane Integration

In active-matrix backplane integration, the manufacturing process for the VTFT array is slightly different from the process for a single device. The process for AMFPI backplane (FIG. 26) is completed at Mask 5 (insulating film passivation) step. The hatched areas 55 in FIG. 26 are the areas for the photodiodes.

For AMLCD backplane (FIG. 27), however, one extra material and photomask step between Mask 4 and 5 are needed to form a transparent pixel electrode 37. This transparent pixel electrode 37 is usually indium tin oxide (ITO) with a typical thickness of 100 nm. HCl solution can be used to etch ITO and pattern the pixel electrode structure. After that, passivation dielectric and contact windows 57a are deposited and patterned, respectively, to complete the process. The hatched areas 58 in FIG. 27 are the areas for the liquid crystal. Therefore, totally 6 photomask steps are needed for AMLCD backplane.

General Process Discussions (Optional):

Purely from the perspective of manufacturing, the realization of the VTFT structure is critically dependent on an appropriate selection of thin film materials and their associated etching conditions that can provide a highly vertical, fully self-aligned, multi-layered channel structure, yet the etching chemistry is still highly selective against other materials that are not the candidates for the vertical channel but are used for other principle electrical functions of the VTFT, e.g. electrical current conduction. Anisotropic etching is usually achievable by RIE, but process conditions must be carefully optimized in order to have the same degree of anisotropy on multiple films of different chemical stoichiometries. While the process recipe for anisotropic etching can be satisfactory, it may not be highly selective against the materials underlying the vertical channel materials. Discovering the combinations of thin film materials and etchants that can both accomplish fully anisotropic etching and high selectivity against underlying material is not a simple task, and very often only a few combinations can meet this challenge.

As a general rule of thumb, the semiconductor materials (a-Si:H, μc-Si:H, and poly-Si) and the dielectric materials (a-SiNₓ:H and a-SiOₓ:H) for the VTFT can be etched by fluorine-, chlorine-, and bromine-based plasma chemistries in an increasing easiness of anisotropy but with an expense of etch rate. Since these materials are used for constructing the vertical channel structure with metal electrodes underneath, it is crucial to find an appropriate choice of plasma etchant and metal electrode such that the etchant can perform anisotropic etching of the vertical channel, while it is also highly selective against the metal electrode. For example, if CHF₃ (fluorine-based) plasma is chosen for the etching of the vertical structure at room temperature, Al, Cr, or Ti can be used for the electrodes to ensure a high selectivity against the chemical attack of F atoms. Similarly, if CF₃Cl (chlorine-based and oxygen-free) plasma is used, Cr, Mo, and W can be good candidates because Cl atoms, predominantly dissociated from CF₃Cl plasma, do not or just weakly attack those metals.

summarizes the etching characteristics of the common thin film materials with three different reactive plasma species. Appropriate selection of the metal electrode and etchant should be made as a starting point of the dry-etch process development for the vertical structure formation. Having a metal that is not or weakly reactive to the choice of plasma etchant also implies that it may be used, after the top (drain) electrode is patterned, as a hard mask for the dry etching of the vertical channel, instead of using a photoresist mask.

Although the above descriptions underline the preferred process arrangement for the manufacture of the VTFT, an ideal combination of the metal electrode and plasma etchant for the vertical channel sometimes cannot be made due to other process constraints. For the less ideal scenarios, one must carefully control the etch time, increase process uniformity, adjust process parameters for better selectivity, and/or use thicker metal films to compensate for the lower selectivity of the selected plasma etchant.

TABLE 1
Physical data and etching characteristics of thin film materials and their plasma etchants.¹

| | Reactive | | B.P.⁵ @ | B.P. @ | | | Physical | Physical | | |
|---|---|---|---|---|---|---|---|---|---|---|
| Material | Species³ | | 760 | 0.75⁶ | | | State @ | State @ | | |
| (ΔH_{f}°², | (ΔH_{f}°, | Reaction | Torr | Torr | ΔH_{f}° | ΔH°⁷ | 0.75 Torr ≈ | 0.75 Torr ≈ | Etch Rate⁹ ≈ | Etch Rate ≈ |
| kJ/mol) | kJ/mol) | Products⁴ | (° C.) | (° C.) | (Kj/mol) | (kJ/mol) | R.T.⁸ | 100° C. | R.T. | 100° C. |
| Al | F (79) | AlF₃ | 1276 | 906 | −1510.4 | −1748.6 | solid | solid | — | — |
| (0) | Cl (121) | AlCl₃ | 181.1 | 97.1 | −704.2 | −1068.1 | solid | gas | — | fast |
| | | Al₂Cl₆ | <181.1 | ≈27¹⁰ | −1290.8 | −2018.6 | gas¹⁰ | gas¹⁰ | very fast | very fast |
| | Br (112) | Al₂Br₆ | no data | ≈57¹⁰ | −970.7 | −1642.1 | gas¹⁰ | gas¹⁰ | fast | very fast |
| Cr | F | CrF₃ | 1400 mp¹¹ | no data | −1159 | −1397.2 | solid | no data | — | No data |
| | Cl + O (371) | CrO₂Cl₂ | 117 | ≈−20 | −579.5 | −1320.5 | gas | gas | very slow | no data |
| | Cl | CrCl₃ | 1300 | no data | −556.5 | −920.4 | solid | no data | — | no data |
| (0) | Br | CrBr₂ | 842 mp | no data | −302.1 | −525.9 | solid | no data | — | no data |
| Mo | F | MoF₆ | 34 | −64 | −1585.7 | −2062.1 | gas | gas | fast | Very fast |
| (0) | Cl + O | MoO₂Cl₂ | 250 | 59.4 | −724 | −1465 | gas | gas | moderate | no data |
| | Cl | MoCl₅ | 268 | no data | −527 | −1133.5 | solid | gas | — | slow |
| | Br | MoBr₃ | 977 mp | no data | −284 | −619.7 | solid | solid | — | — |
| Ta | F | TaF₅ | 229 | ≈55 | −1903.6 | −2300.6 | gas | gas | fast | Fast |
| (0) | Cl | TaCl₅ | 233 | −24.9 | −859 | −1465.5 | gas | gas | fast | no data |
| | Br | TaBr₅ | 345 | ≈166 | −598.3 | −1157.8 | solid | gas | — | no data |
| Ti | F | TiF₄ | 284 mp | no data | −1649 | −1966.6 | solid | no data | — | No data |
| (0) | Cl | TiCl₄ | 136.5 | ≈−20 | −804.2 | −1289.4 | gas | gas | fast | Fast |
| | Br | TiBr₄ | 234 | 139.6 | −616.7 | −1064.3 | solid | solid | — | — |
| W | F | WF₆ | 17 | −74 | −1721.7 | −2198.1 | gas | gas | fast | No data |
| (0) | Cl | WCl₆ | 346.8 | 98.5 | −602.5 | −1330.3 | gas | gas | slow | Moderate |
| | Br | WBr₆ | 327 | no data | −348.5 | −1019.9 | gas | no data | slow | no data |
| Si | F | SiF₄ | −86 | −145.6 | −1615 | −1932.6 | gas | gas | very fast | Very fast |
| (0) | Cl | SiCl₄ | 57.7 | <<−39 | −657 | −1142.2 | gas | gas | fast | Fast |
| | Br | SiBr₄ | 154 | no data | −415.5 | −863.1 | gas | gas | moderate | Moderate |
| SiO₂¹² | F₂ (0) | SiF₄+ | −86 | −145.6 | −1615 | −704.3 | gas | gas | very slow | Very |
| (−910.7) | Cl₂ (0) | SiCl₄+ | 57.7 | <<−39 | −657 | 253.7 | gas | gas | — | slow |
| | Br₂ (0) | SiBr₄+ | 154 | no data | −415.5 | 495.2 | gas | gas | — | — |
| | | O₂ | −183 | <−211.9 | 0 | | gas | | | |
| Si₃N₄¹² | F₂ | SiF₄+ | −86 | −145.6 | −1615 | exoth. | gas | gas | very slow | Slow |
| (−743.5) | Cl₂ | SiCl₄+ | 57.7 | <<−39 | −657 | endoth. | gas | gas | — | — |
| | Br₂ | SiBr₄+ | 154 | no data | −415.5 | Endoth. | gas | gas | — | — |
| | | N₂ | −196 | −226.8 | 0 | | gas | | | |
| ¹References obtained from various chemistry handbooks and journal articles. | | | | | | | | | | |
| ²ΔH_{f}° = heat (enthalpy) of formation of the element or compound. | | | | | | | | | | |
| ³Only reactive neutral atoms generated from the plasma are considered for simplicity. F atoms usually come from the source gases of F₂, CF₄, CHF₃, C₂F₆, NF₃, SF₆, etc.; | | | | | | | | | | |
| # Cl atoms from Cl₂, CCl₄, CF₃Cl, BCl₃, SiCl₄, HCl, etc.; Br atoms from HBr, CF₃Br, etc; O atoms from O₂, H₂O, etc. | | | | | | | | | | |

⁴Only main reaction products are considered.
⁵B.P. = boiling point.
⁶Most RIE processes are usually performed under pressure below 0.75 Torr.
⁷ΔH° = heat (enthalpy) of reaction between the thin film material and the plasma species.
⁸R.T. = room temperature.
⁹In nm/min: very fast (>1000); fast (100˜1000); moderate (50˜100); slow (10˜50); very slow (<10).
¹⁰Boiling points and physical states in plasma are evaluated at 7.5 mTorr in this case.
¹¹mp = melting point. Note that boiling point information for this compound is not available.
¹²Only reactions with F₂, Cl₂, and Br₂, are illustrated, but they are reactive with other halogen-based gases following the same trend of reactivity. Selectivity with Si are often altered by O₂ or H₂ additive gases.

1. A vertical thin film transistor comprising a substrate; a first electrode film formed on the substrate with a linewidth (the edge of the line is slightly widened to provide margin for alignment purpose only); a first heavily doped n⁺ semiconductor film formed on and aligned to the first electrode; a first heavily doped p⁺ semiconductor film formed on and aligned to the first n⁺ semiconductor film; a first insulating film formed on the first p⁺ semiconductor film with a second linewidth, which is the same as, parallel to, and aligned to the first linewidth but extended to the opposite direction, and the edge of this second line overlaps with the edge of the first line; a second heavily doped p⁺ semiconductor film formed on and aligned to the first insulating film; a second heavily doped n⁺ semiconductor film formed on and aligned to the second p⁺ semiconductor film; a second electrode film formed on and aligned to the second n⁺ semiconductor film; an undoped semiconductor film formed on the sidewall of the second line and on some overlap area of the first and second lines with a third linewidth, which is the same as and orthogonal to the first and second linewidths; a second insulating film formed on and aligned to the undoped semiconductor film; and a third electrode film formed on and aligned to the second insulating film.

2-39. (canceled)
